(19) United States
(12) Patent Application Publication
(10) Pub. No.: US 2006/0033207 A1
(43) Pub. Date: Feb. 16, 2006

(54) Microwave-monolithic-integrated-circuit-mounted substrate, transmitter device for transmission only and transceiver device for transmission/reception in microwave-band communication

(75) Inventors: Makio Nakamura, Osaka-shi (JP); Shunji Enokuma, Osakasayama-shi (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/002,636

(22) Filed: Dec. 3, 2004

(30) Foreign Application Priority Data
Dec. 4, 2003 (JP) 2003-405961 (P)
Oct. 5, 2004 (JP) 2004-292417 (P)

(51) Int. Cl. H01L 23/34

(52) U.S. Cl. 257/728

(57) ABSTRACT

An MMIC (Microwave Monolithic Integrated Circuit)-mounted substrate includes a double-metal-foil dielectric substrate having a dielectric substrate with a metal foil pattern formed on both sides of the substrate, an MMIC that is a surface-mount high power amplifier mounted on one side of the double-metal-foil dielectric substrate, and a metal chassis attached to the other side of the double-metal-foil dielectric substrate. The double-metal-foil dielectric substrate has a plurality of through holes. A copper foil pattern that is a metal foil pattern continuously extends to cover the inner surfaces of the through holes and both sides of the dielectric substrate, and solder is buried in the through holes.

This nonprovisional application is based on Japanese Patent Applications Nos. 2003-405961 and 2004-292417 filed with the Japan Patent Office on Dec. 4, 2003, and Oct. 5, 2004, respectively, the entire contents of which are hereby incorporated by reference.

### BACKGROUND OF THE INVENTION

1. Field of the Invention

The present invention relates to a substrate having a microwave monolithic integrated circuit (hereinafter referred to as “MMIC”) mounted thereon. The MMIC-mounted substrate is chiefly used in transmission devices for satellite communication, particularly in Ku-band transceivers and Ku-band transmitters.

2. Description of the Background Art

Japanese Utility Model Laying-Open No. 5-31307 discloses a conventional technique of promoting heat dissipation of a high output transistor of a high power amplifier. Further, Japanese Patent Laying-Open No. 2003-060523 discloses a conventional technique of mounting a semiconductor device, which generates a large amount of heat, of a radio communication module, on a multilayer substrate. For both of the two publications, a depressed part has to be provided in a region of the substrate where a chip is mounted.

A technique as discussed below has been known as a method of mounting a necessary chip on a substrate without depressed part in the substrate while efficiently dissipating heat from the chip.

Referring to FIGS. 16 and 17, a description is given below of an MMIC-mounted substrate having an MMIC which is a conventional high power amplifier (HPA) mounted on the substrate. As shown in FIG. 16, the MMIC-mounted substrate includes a double-metal-foil dielectric substrate 2 and a metal chassis 3 attached to one side of the substrate. Double-metal-foil dielectric substrate 2 has a metal foil pattern produced by attaching a metal foil to both sides of a dielectric substrate and then partially removing the metal foil by such a method as etching to make some pattern. In the example herein shown, the metal foil pattern is a copper foil pattern, and double-metal-foil dielectric substrate 2 has the copper foil pattern (not shown) with a certain pattern shape formed on both sides of the dielectric substrate. FIG. 17 is an enlarged view of the MMIC which is the high power amplifier. The high power amplifier, namely MMIC has to address the problem of heat generation. Therefore, for efficient heat dissipation and grounding, a metal flange 7b is provided on the lower end of a side of an MMIC body 7a to produce a flanged MMIC 7. Further, a plurality of terminals 7c protrude from the lower end of another side, which is different from the side on which flange 7b of MMIC body 7a is provided.

As shown in FIG. 16, double-metal-foil dielectric substrate 2 has an attachment hole 8 which is a through hole corresponding in size to flanged MMIC 7. In attachment hole 8, a surface of metal chassis 3 is exposed. Flanged MMIC 7 is connected to the surface of metal chassis 3 via attachment hole 8 of double-metal-foil dielectric substrate 2. Specifically, flanged MMIC 7 is directly fixed to the surface of metal chassis 3 with screws 4 using through holes in flange 7. FIG. 18 is a plan view of flanged MMIC 7 in the fixed state. MMIC body 7a is held in attachment hole 8 to directly contact the surface of metal chassis 3. Terminals 7c protruding from the lateral sides of MMIC body 7a extend out of attachment hole 8 to be placed on respective copper foil patterns 2c on the front side of double-metal foil dielectric substrate 2 and soldered by handwork to respective copper foil patterns 2c.

Terminals 7c are classified into two groups, namely ground terminal 7c1 and signal terminal 7c2. As well, copper foil patterns 2c are roughly classified into two groups, namely ground pattern 2c and signal pattern 2c2. Ground terminal 7c1 is connected to ground pattern 2c1 and signal terminal 7c2 is connected to signal pattern 2c2.

A problem in the aforementioned conventional techniques is that the flanged MMIC, not a simple MMIC, has to be prepared as a high power amplifier.

In addition, since flanged MMIC 7 is mounted on the surface of metal chassis 3 that is exposed in attachment hole 8, not on the upper surface of double-metal-foil dielectric substrate 2, it is necessary to first tighten screws 4 in metal chassis 3 before the soldering. Accordingly, terminals 7c are soldered in the state where metal chassis 3 having a large heat capacity has already been attached. In this state, even if the whole is heated in a reflow bath, most of the heat is taken by metal chassis 3 and thus the soldering of good quality cannot be accomplished. Therefore, unlike common surface-mount components, it is impossible to apply solder in advance to the substrate and mount components and simultaneously complete soldering. This means that flanged MMIC 7 is first secured to metal chassis 3 with screws 4 and thereafter terminals 7c are soldered by handwork, possibly causing deterioration in reliability due to the handwork.

### SUMMARY OF THE INVENTION

An object of the present invention is to provide an MMIC-mounted substrate that requires no flanged MMIC to be prepared, can be assembled without handwork soldering and can efficiently dissipate heat.

With the purpose of achieving the aforementioned object, an MMIC-mounted substrate according to the present invention includes a double-metal-foil dielectric substrate having a dielectric substrate and a metal foil provided on both sides of the dielectric substrate, an MMIC that is a surface-mount high power amplifier mounted on one side of the double-metal-foil dielectric substrate, and a metal chassis attached to the other side of the double-metal-foil dielectric substrate. The double-metal-foil dielectric substrate has a plurality of through holes, the metal foil continuously extends to cover respective inner surfaces of the through holes and the both sides of the dielectric substrate, and solder is buried in the through holes. This structure can be employed to eliminate the necessity to prepare a flanged MMIC. Soldering can be done using the solder within the through holes, and thus no handwork is required to accomplish the soldering. Further, since heat conveyed from the MMIC to the metal foil on the front side of the double-metal-foil dielectric substrate can be transmitted speedily via the solder in the through holes to the metal chassis on the rear side of the double-metal-foil dielectric substrate, heat can efficiently be dissipated. Moreover, by providing the through holes in the metal foil connected to a terminal of the MMIC, electrical connection to the metal chassis can be made at a low electrical resistance, and thus operation at high frequencies can be stabilized.

Preferably, according to the present invention, the metal foil is plated with gold. This structure can be employed to prevent corrosion and improve the thickness precision and thereby stabilize surface state. Accordingly, in using microwaves, characteristics are made stable.

Preferably, according to the present invention, the metal foil is plated with solder. This structure can be employed to improve conformability of solder applied later in the soldering process.

Preferably, according to the present invention, the solder is cream solder. This structure can be employed to easily produce the structure having solder buried in the through hole substantially by only a conventional process of mounting components, namely screen printing and annealing in a reflow bath.

Preferably, according to the present invention, the MMIC-mounted substrate further includes a screw contacting the metal foil and passed through the double-metal-foil dielectric substrate to be connected to the metal chassis. This structure can be employed to allow heat generated from the MMIC and conveyed to the metal foil on the front side of the double-metal-foil dielectric substrate to be transmitted via the screw, in addition to the solder in the through holes and thus efficient heat dissipation is accomplished. As well, electrical connection from a terminal of the MMIC to the metal chassis can be made via the screw to minimize electrical resistance.

Preferably, according to the present invention, the MMIC-mounted substrate further includes a heat dissipation plate contacting a top surface of the MMIC, and the screw is passed through the heat dissipation plate to be fastened while pressing the heat dissipation plate against the MMIC. This structure can be employed to dissipate heat from the top surface of the MMIC by means of the heat dissipation plate, and heat can more efficiently be dissipated from the MMIC.

Preferably, according to the present invention, the screw is passed through a washer and the washer is sandwiched between a head of the screw and the double-metal-foil dielectric substrate. This structure can be employed to prevent the screw from loosening due to changes with time.

Preferably, according to the present invention, the MIC-mounted substrate further includes a heat dissipation plate contacting a top surface of the MMIC, the heat dissipation plate including a plate portion and a screw portion, the plate portion and the screw portion formed in one piece, and the screw portion passed through the double-metal-foil dielectric substrate and the metal chassis to be caught on the rear side of the metal chassis. This structure can be employed to make the plate portion planar with no protrusion therefrom, and thus the height from the front side of the double-metal-foil dielectric substrate can be reduced.

According to the present invention, there is no necessity to prepare a flanged MMIC. The solder in the through holes can be used for soldering and thus the soldering can be accomplished without handwork. The heat transmitted from the MMIC to the metal foil on the font side of the double-metal-foil dielectric substrate can immediately be transmitted to the metal chassis on the rear side of the double-metal-foil dielectric substrate via the solder in the through holes, and thus the heat can efficiently be dissipated. The through holes can be provided in the metal foil contacting a terminal of the MMIC to make electrical connection to the metal chassis at a low electrical resistance and thereby stabilize operation at high frequencies.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an exploded perspective view of an MMIC-mounted substrate according to a first embodiment of the present invention.

FIG. 2 is a partial enlarged cross sectional view of the MMIC-mounted substrate according to the first embodiment of the present invention.

FIG. 3 is a partial enlarged view of a region of an MMIC and therearound that is mounted on a surface of a double-metal-foil dielectric substrate according to the first embodiment of the present invention.

FIG. 4 is a partial enlarged cross sectional view of the region of the MMIC and therearound of the MMIC-mounted substrate according to the first embodiment of the present invention.

FIG. 5 is a transverse cross sectional view of a connecting portion of a terminal and a copper foil pattern according to the first embodiment of the present invention.

FIG. 6 is a partial enlarged plan view of the MMIC-mounted substrate without an MMIC body according to the first embodiment of the present invention.

FIG. 7 is an exploded perspective view of an MMIC-mounted substrate according to a second embodiment of the present invention.

FIG. 8 is a partial enlarged plan view of the MMIC-mounted substrate without screws according to the second embodiment of the present invention.

FIG. 9 is a perspective view of a screw and therearound according to the second embodiment of the present invention.

FIG. 10 is an exploded perspective view of an MMIC-mounted substrate according to a third embodiment of the present invention.

FIG. 11 is a partial enlarged cross sectional view of an MMIC and therearound of the MMIC-mounted substrate according to the third embodiment of the present invention.

FIG. 12 is an exploded perspective view of an MMIC-mounted substrate according to a fourth embodiment of the present invention.

FIG. 13 is a partial enlarged cross sectional view of an MMIC and therearound of the MMIC-mounted substrate according to the fourth embodiment of the present invention.

FIG. 14 is a circuit block diagram of a transmitter device according to a fifth embodiment of the present invention.

FIG. 15 is a circuit block diagram of a transceiver device according to a sixth embodiment of the present invention.

FIG. 16 is an exploded perspective view of a conventional MMIC-mounted substrate.

FIG. 17 is a perspective view of a conventional MMIC.

FIG. 18 is a plan view of the conventional MMIC in a fixed state.

### DESCRIPTION OF THE PREFERRED EMBODIMENTS

### First Embodiment

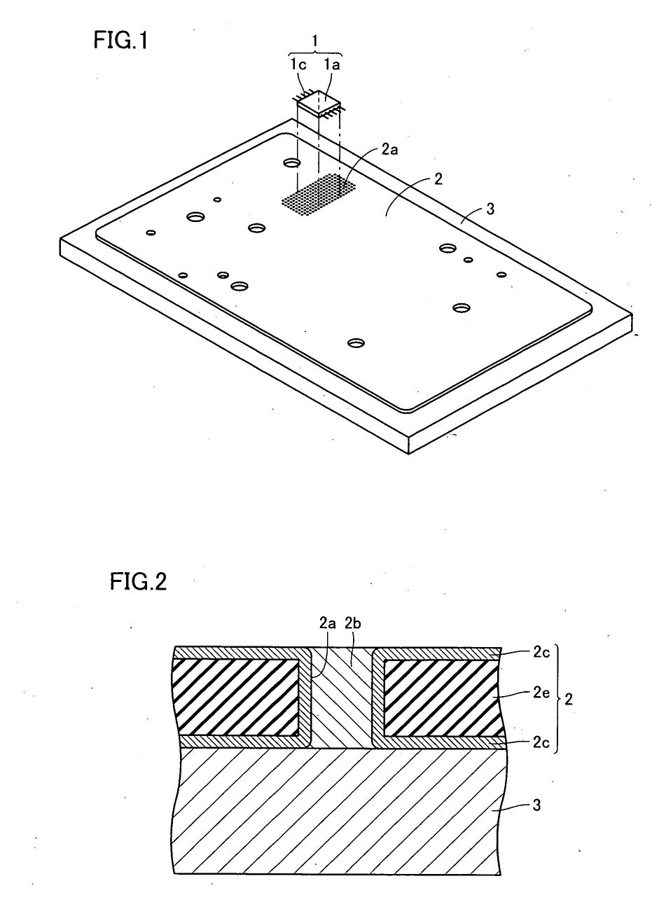

Referring to FIGS. 1 to 6, an MMIC-mounted substrate according to a first embodiment of the present invention is described. The MMIC-mounted substrate, as shown in FIG. 1, includes a double-metal-foil dielectric substrate 2, an MMIC 1 and a metal chassis 3. In FIG. 1, for the purpose of convenience of description, MMIC 1 is shown to be apart from double-metal-foil dielectric substrate 2. MMIC 1 is a surface-mount high power amplifier and is provided on one side of double-metal-foil dielectric substrate 2. To the other side of double-metal-foil dielectric substrate 2, metal chassis 3 is attached. FIG. 2 is a partial enlarged cross sectional view of the MMIC-mounted substrate shown in FIG. 1. Double-metal-foil dielectric substrate 2 has, as shown in FIG. 2, a copper foil pattern 2c as a metal foil pattern formed on both sides of a dielectric substrate 2e. Double-metal-foil dielectric substrate 2 has a region where a number of through holes 2a are arranged. MMIC 1 is mounted in such a region.

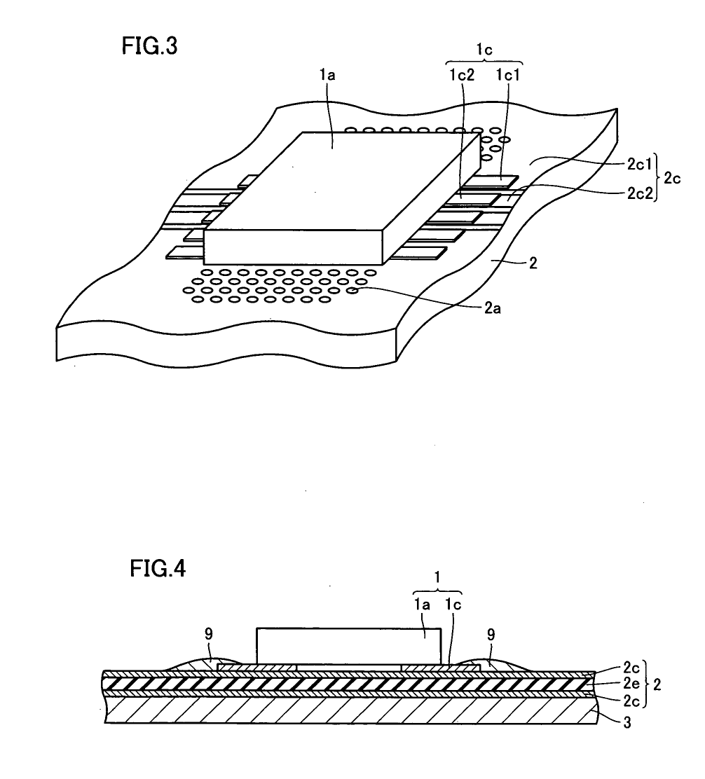

FIG. 3 is an enlarged view of a region of MMIC 1 and therearound that is mounted on a surface of double-metal-foil dielectric substrate 2. Metal chassis 3 is not shown in FIG. 3.

MMIC 1 includes an MMIC body 1a and terminals 1c extending from both sides of MMIC body 1c. Terminals 1c are roughly classified into two groups, namely ground terminal 1c1 and signal terminal 1c2. There are provided several signal terminals 1c2 and several signal patterns 2c2. Although four signal terminals and four signal patterns are shown in FIG. 3, the number of the terminals and patterns is not limited to four. Ground pattern 2c1 and signal pattern 2c2 are electrically independent of each other. Ground terminal 1c1 is connected to ground pattern 2c1 and signal terminal 1c2 is connected to signal pattern 2c2. FIG. 4 shows a cross section of the structure in FIG. 3. As shown in FIG. 4, each terminal 1c is connected to a corresponding copper foil pattern 2c by solder 9. As an example, a transverse cross section of a connecting portion of terminal 1c2 and copper foil pattern 2c2 is shown in FIG. 5.

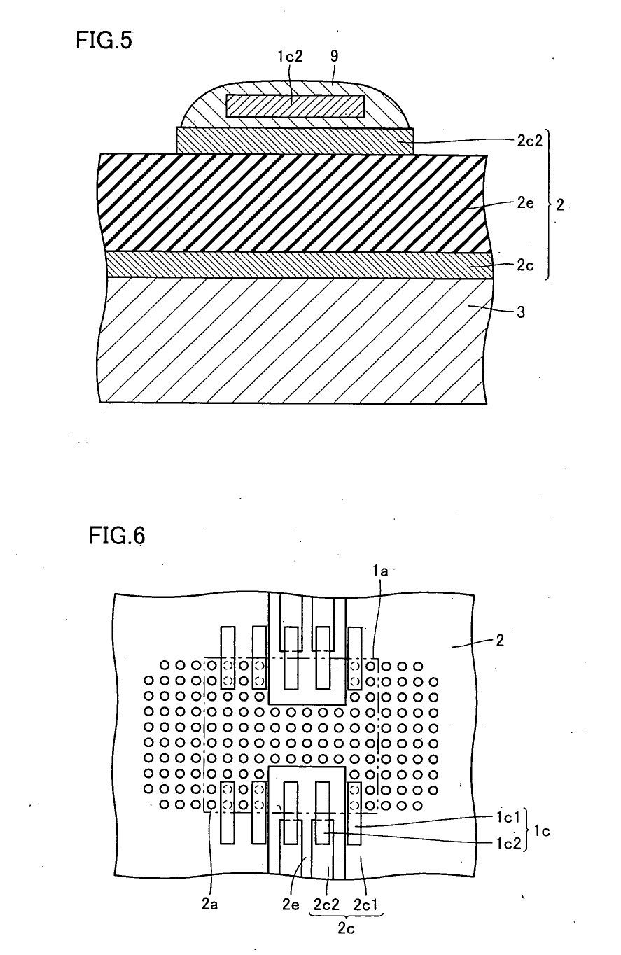

For illustration of a two-dimensional positional relation between terminals 1c, copper foil patterns 2c and through holes 2a, FIG. 6 shows a plan view of the structure in FIG. 3 without MMIC body 1a. In FIG. 6, a region occupied by MMIC body 1a is indicated by the chain double-dashed line. As shown in FIG. 6, in a region of ground pattern 2c1 that is located under MMIC body 1a, including a region thereof located under ground terminals 1c1, through holes 2a are arranged. In contrast, in a region under signal terminals 1c2 and a region of signal patterns 2c2, no through hole 2a is provided. In through hole 2a as shown in FIG. 2, the inner surface of through hole 2a is covered with the metal foil and the metal foil on the front side and the metal foil on the rear side of double-metal-foil dielectric substrate 2 are electrically connected to each other. Moreover, solder is buried in each through hole 2a to form a solder-buried portion 2b. Since ground terminal 1c1 contacts the front surface of double-metal-foil dielectric substrate 2, ground terminal 1c1 is electrically connected to copper foil pattern 2c on the rear surface of double-metal-foil dielectric substrate 2.

According to this embodiment, ground terminal 1c1 of MMIC 1 is connected to metal chassis 3 via copper foil pattern 2c on the front side of double-metal-foil dielectric substrate 2, solder-buried portion 2b of through hole 2a and copper foil pattern 2c on the rear side of double-metal-foil dielectric substrate 2 in this order, namely they are all metals connected to each other. Therefore, through this metal path, heat dissipation and grounding to metal chassis 3 can be done. Solder-buried portion 2b filled with the metal has a significantly higher thermal conductivity than dielectric substrate 2e. The presence of such solder-buried portion 2b remarkably improves the efficiency of thermal conduction from the front side to the rear side of double-metal-foil dielectric substrate 2. The efficiency of heat dissipation of MMIC 1 which is a high power amplifier can thus be improved.

Regarding the grounding as well, since electrical connection between the front side and the rear side of double-metal-foil dielectric substrate 2 can be made via the solder in many through holes 2a, the electrical resistance can be decreased to allow operation to stably be done even for operation at a high frequency of several GHz or higher.

In a region of signal pattern 2c2, signal terminal 1c2 and signal pattern 2c2 are electrically connected to communicate signals. In this region, no through hole 2a is provided and thus any component involved in the signals can be electrically isolated from any components such as ground pattern 2c1 and copper foil pattern 2c on the rear side.

If, however, electrical isolation from any components involved in the grounding can be maintained, the through hole may be provided in the region of the signal pattern. In this case as well, solder may be buried in the through hole for establishing electrical connection with the rear side of double-metal-foil dielectric substrate 2 at a low resistance.

Preferably, copper foil pattern 2c is plated with gold. The gold plating can prevent corrosion and facilitate enhancement of thickness precision to provide a stable surface state. When the MMIC-mounted substrate is used in microwave applications, energy concentrates on the surface of copper foil pattern 2c because of the skin effect of the microwave. In such a case, the stable surface state stabilizes characteristics. In particular, it is preferable to gold-plate copper foil pattern 2c on both sides of double-metal-foil dielectric substrate 2.

Still preferably, copper foil pattern 2c on both sides of double-metal-foil dielectric substrate 2 is plated with solder, which enhances conformability of solder applied later in the soldering process.

Preferably, the solder in solder-buried portion 2b is cream solder. With the cream solder, substantially by only a conventional process for mounting components, solder-buried portion 2b can automatically be formed. In other words, without additional process, through hole 2a can be filled with the solder by a method described below.

Before soldering surface-mount components, cream solder is applied by screen printing to a surface region of double-metal-foil dielectric substrate 2 where the components are to be mounted and a region where through holes 2a are arranged. In mounting surface-mount components, there has conventionally been a process of applying cream solder to a region where the components are to be mounted. According to the present invention, the solder is applied additionally to the region where through holes 2a are arranged.

Then, each component is placed by a mechanical mounter on the front surface of double-metal-foil dielectric substrate 2. At this stage, metal chassis 3 has not been attached. Double-metal-foil dielectric substrate 2 with the component mounted on its front surface is processed in a reflow bath. Being subjected to a high temperature in the reflow bath, the cream solder is melt so that the mounted component is soldered to the front surface of double-metal-foil dielectric substrate 2. Into through holes 2a, the solder flows to form solder-buried portion 2b. In other words, soldering of the component and the formation of solder-buried portion 2b can simultaneously be accomplished. After this, to the rear side of double-metal-foil dielectric substrate 2, metal chassis 3 is attached.

### Second Embodiment

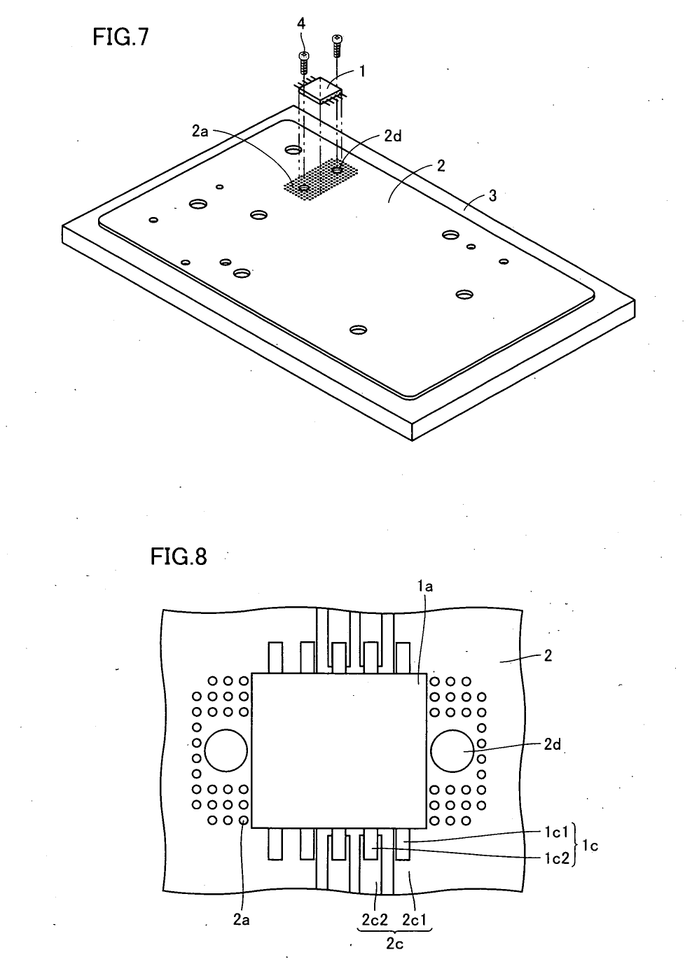

Referring to FIGS. 7 to 9, an MMIC-mounted substrate according to a second embodiment of the present invention is described. The MMIC-mounted substrate, as shown in FIG. 7, includes a double-metal-foil dielectric substrate 2, an MMIC 1, a metal chassis 3, and screws 4. In FIG. 7, for the purpose of convenience of description, MMIC 1 is shown to be apart from double-metal-foil dielectric substrate 2. Screws 4 are passed through double-metal-foil dielectric substrate 2 to be connected to metal chassis 3. FIG. 8 is a plan view before screws 4 are attached. As shown in FIG. 8, screw holes 2d are provided outside the region, occupied by an MMIC body 1a, of double-metal-foil dielectric substrate 2, and relatively close to MMIC body 1a. Screw holes 2d are provided in ground pattern 2c1.

Screw 4 is tightened in screw hole 2d as shown in FIG. 9. Screw 4 is apart from MMIC 1.

When screw 4 is tightened, screw 4 may directly be tightened and fastened to ground pattern 2c1. More preferably, as shown in FIG. 9, a metal washer 10 is used. In this case, screw 4 passes through washer 10 and washer 10 is sandwiched between the head of screw 4 and double-metal-foil dielectric substrate 2. Thus, loosening of screw 4 due to changes with time can be prevented. Washer 10 may overlap through hole 2a.

Any of the aforementioned arrangements allows screw 4 to contact ground pattern 2c1, which is a metal foil attached to the front side of double-metal-foil dielectric substrate 2, directly or via washer 10 only.

Other components and structure except those discussed above are similar to those described in connection with the first embodiment, and the description thereof is not repeated.

According to this embodiment, screws 4 are attached by being passed through double-metal-foil dielectric substrate 2 to reach metal chassis 3 in the vicinity of the region where MMIC 1 is mounted. Therefore, heat generated from MMIC 1 and conveyed to copper foil pattern 2c on the front side of double-metal-foil dielectric substrate 2 can pass through screws 4 in addition to solder-buried portion 2b of through hole 2a to reach metal chassis 3. Thus, the heat is conveyed via screws 4 which are more advantageous in terms of thermal conduction than solder-buried portion 2b, so that the heat can immediately be dissipated to metal chassis 3. This advantage is still achieved when washer 10 is used. Since washer 10 is made of metal, the heat held by ground pattern 2c1 is dissipated to metal chassis 3 via washer 10 and screw 4.

Regarding the grounding as well, the grounding via screw 4 larger in diameter than through hole 2a can reduce electrical resistance between the front and rear sides of double-metal-foil dielectric substrate 2. Accordingly, grounding can efficiently be done.

Although screw holes 2d are provided at respective two places in this example, the number of the screw locations is not limited to two and at least one screw may be used.

### Third Embodiment

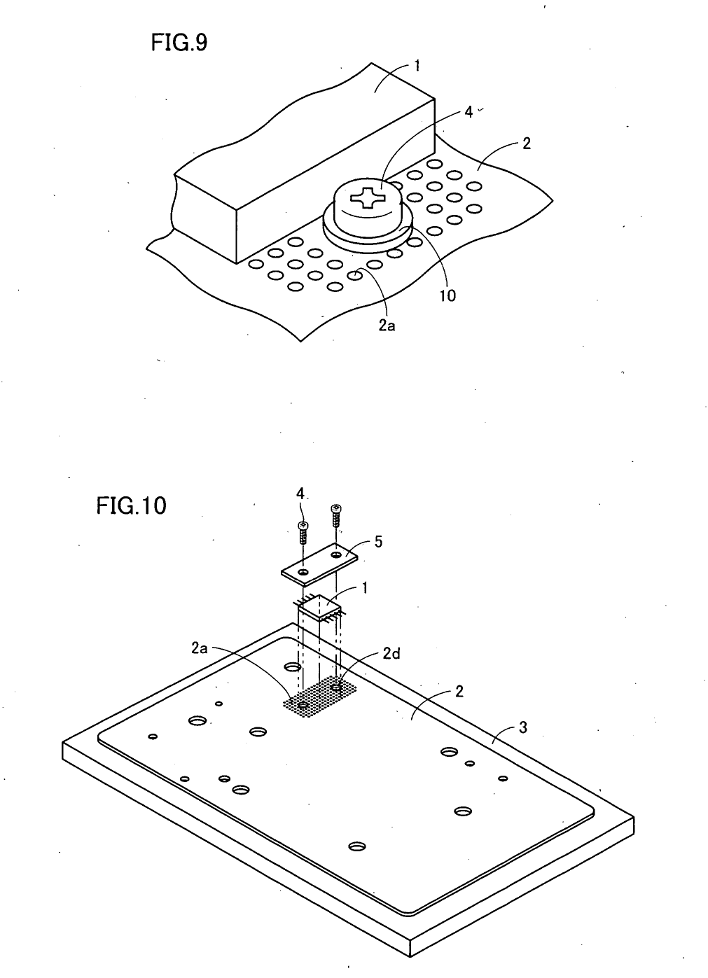

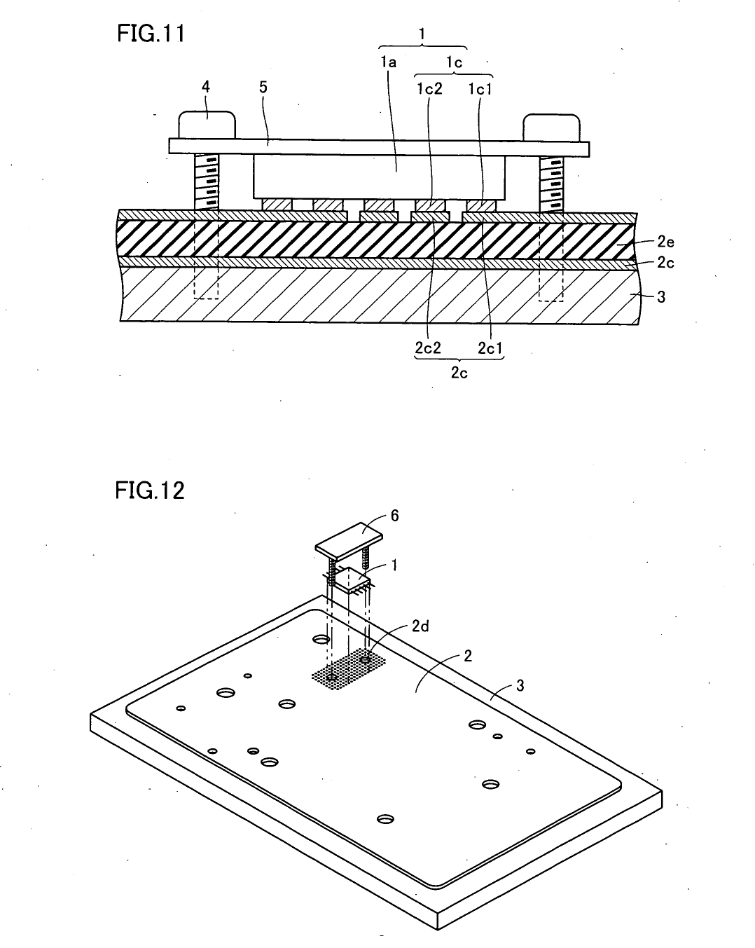

Referring to FIGS. 10 and 11, an MMIC-mounted substrate according to a third embodiment of the present invention is described. The MMIC-mounted substrate includes, as shown in FIG. 10, a double-metal-foil dielectric substrate 2, an MMIC 1, a metal chassis 3, a heat dissipation plate 5, and screws 4. In FIG. 10, for the purpose of convenience of description, MMIC 1 is shown to be apart from double-metal-foil dielectric substrate 2. Heat dissipation plate 5 is in contact with the top surface of MMIC 1 and has through holes for passing screws 4 therethrough. Heat dissipation plate 5 is preferably made of metal. Screws 4 are passed through heat dissipation plate 5 and fastened while pressing heat dissipation plate 5 against MMIC 1, which is shown in the cross section of FIG. 11.

Other components and structure except those discussed above are similar to those described in connection with the first and second embodiments, and the description thereof is not repeated.

According to this embodiment, in addition to the effects as described in connection with the second embodiment, namely efficient heat dissipation and grounding to metal chassis 3 via screws 4, a further effect of more efficient heat dissipation from MMIC 1 can be achieved since heat can be released from the top surface of MMIC 1 by heat dissipation plate 5. The heat released from the top surface of MMIC 1 is conveyed to heat dissipation plate 5, partially dissipated from heat dissipation plate 5 into the air and the remaining heat is transmitted via screws 4 to metal chassis 3.

Although heat dissipation plate 5 is supported by two screws 4 in this example, the number of screws supporting heat dissipation plate 5 is not limited to two and may be any number of at least one. Moreover, the largest possible area of heat dissipation plate 5 is preferably in contact with MMIC 1. Heat dissipation plate 5 is not limited to the one in the shape of the flat plate and may be any uneven or curved plate.

### Fourth Embodiment

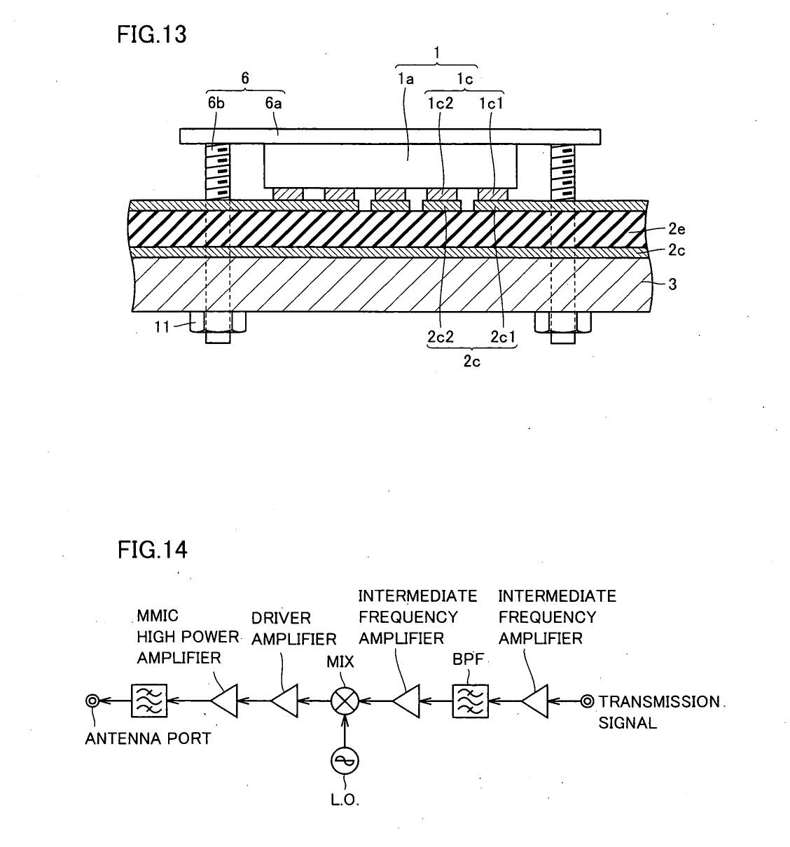

Referring to FIGS. 12 and 13, an MMIC-mounted substrate according to a fourth embodiment of the present invention is described. The MMIC-mounted substrate includes, as shown in FIG. 12, a double-metal-foil dielectric substrate 2, an MMIC 1, a metal chassis 3, and a heat dissipation plate 6. In FIG. 12, for the purpose of convenience of description, MMIC 1 is shown to be apart from double-metal-foil dielectric substrate 2. As shown in FIG. 13, heat dissipation plate 6 contacts the top surface of MMIC 1. Heat dissipation plate 6 includes a plate portion 6a and screw portions 6b. Plate portion 6a and screw portions 6b are formed in one piece. Heat dissipation plate 6 is preferably made of metal. Screw portions 6b pass through double-metal-foil dielectric substrate 2 and metal chassis 3. The leading ends of screw portions 6b protrude from the rear side of metal chassis 3 and the protruded parts are caught by nuts 11.

Other components and structure except those discussed above are similar to those described in connection with the first embodiment, and the description thereof is not repeated.

According to this embodiment, in addition to the effects as described in connection with the second embodiment, namely efficient heat dissipation and grounding to metal chassis 3 via screws 4, a further effect of more efficient heat dissipation from MMIC 1 can be achieved since heat can be released from the top surface of MMIC 1 by heat dissipation plate 6. The heat released from the top surface of MMIC 1 is conveyed to plate portion 6a of heat dissipation plate 6, partially dissipated from plate portion 6a into the air and the remaining heat is transmitted via screw portions 6b to metal chassis 3.

Moreover, since heat dissipation plate 6 is comprised of plate portion 6a and screw portions 6b that are formed in one piece, the heads of the screws do not protrude from the top of the plate portion so that the height from double-metal-foil dielectric substrate 2 can be reduced.

Although two screw portions 6b are provided in this example, the number of screw portions 6b of heat dissipation plate 6 is not limited to two and may be any number of at least one. Further, the one-piece screw portions and separate screws as shown in connection with the third embodiment may be combined for use. Moreover, the largest possible area of heat dissipation plate 6 is preferably in contact with MMIC 1. Plate portion 6a is not limited to the one in the shape of the flat plate and may be any uneven or curved plate.

### Fifth Embodiment

Referring to FIG. 14, a transmitter device according to a fifth embodiment of the present invention is described. This transmitter device is used in microwave-band communication for transmission only. FIG. 14 shows a circuit block diagram of the transmitter device. In the transmitter device, a transmission signal provided via intermediate frequency amplifiers (IF amplifiers) and a bandpass filter (BPF) is converted by a mixer (MIX) into a high-frequency signal in the microwave band. Further, the transmission signal converted into the high-frequency signal and provided via a driver amplifier is power-amplified by an MMIC high power amplifier. The MMIC high power amplifier includes the MMIC-mounted substrate described above in connection with the embodiments each.

The transmitter device has the MMIC-mounted substrate described above in connection with the embodiments each, so that the transmitter device can efficiently dissipate heat to serve as a reliable transmitter device.

### Sixth Embodiment

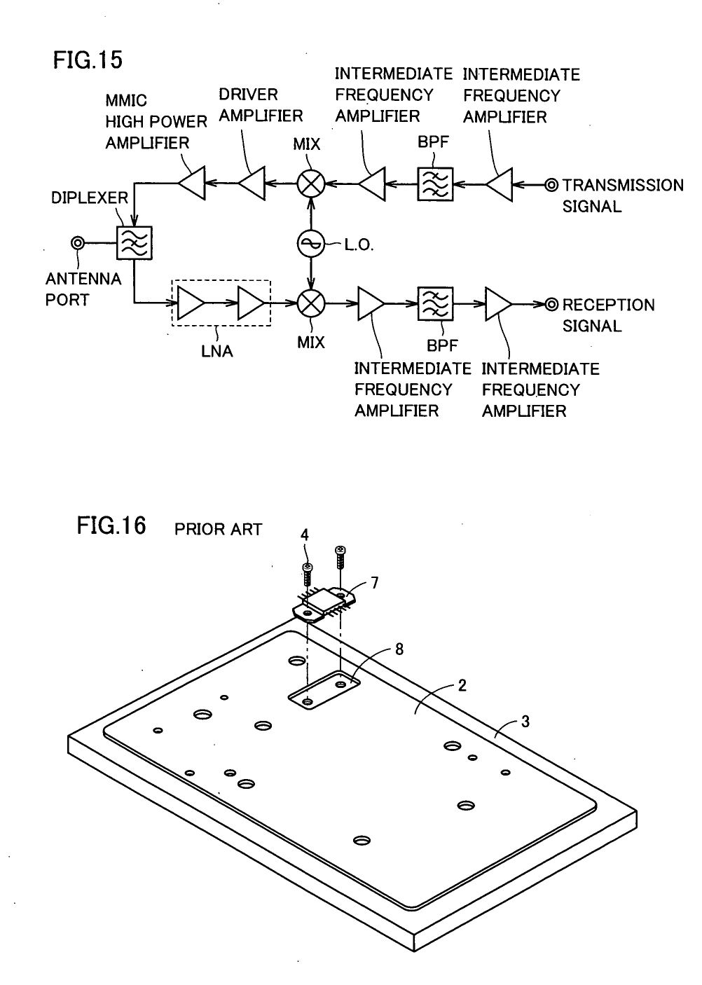

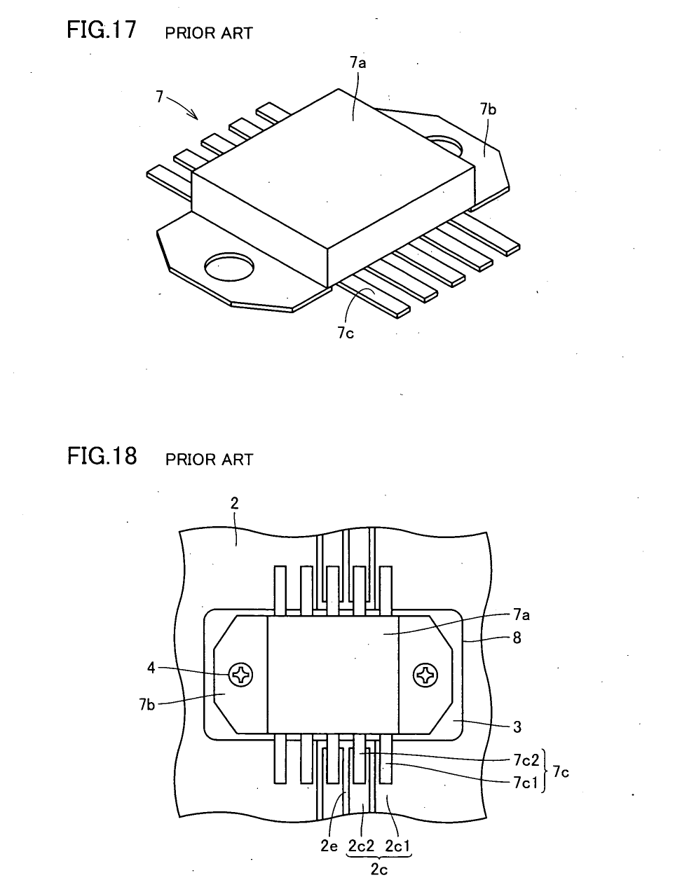

Referring to FIG. 15, a transceiver device according to a sixth embodiment of the present invention is described. This transceiver device is used in microwave-band communication for transmission/reception. Namely, the transceiver device has both of transmission function and reception function. FIG. 15 shows a circuit block diagram of the transceiver device. In this transceiver device as well, a transmission signal is transferred through the same path as that described in connection with the fifth embodiment and power-amplified by an MMIC high power amplifier. The MMIC high power amplifier includes the MMIC-mounted substrate described above in connection with the embodiments each.

The transceiver device has the MMIC-mounted substrate described above in connection with the embodiments each, so that the transceiver device can efficiently dissipate heat to serve as a reliable transceiver device.

Although the above-described embodiments each include the copper foil as the metal foil attached to both sides of the dielectric substrate, the metal foil may be of any material other than copper.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. An MMIC-mounted substrate comprising:
a double-metal-foil dielectric substrate including a dielectric substrate and a metal foil provided on both sides of said dielectric substrate;
an MMIC that is a surface-mount high power amplifier mounted on one side of said double-metal-foil dielectric substrate; and
a metal chassis attached to the other side of said double-metal-foil dielectric substrate, wherein
said double-metal-foil dielectric substrate has a plurality of through holes, said metal foil continuously extends to cover respective inner surfaces of said through holes and said both sides of said dielectric substrate, and solder is buried in said plurality of through holes.

2. The MMIC-mounted substrate according to claim 1, wherein
said metal foil is plated with gold.

3. The MMIC-mounted substrate according to claim 1, wherein
said metal foil is plated with solder.

4. The MMIC-mounted substrate according to claim 1, wherein
said solder is cream solder.

5. The MMIC-mounted substrate according to claim 1, further comprising a screw contacting said metal foil and passed through said double-metal-foil dielectric substrate to be connected to said metal chassis.

6. The MMIC-mounted substrate according to claim 5, further comprising a heat dissipation plate contacting a top surface of said MMIC, wherein said screw is passed through said heat dissipation plate to be fastened while pressing said heat dissipation plate against said MMIC.

7. The MMIC-mounted substrate according to claim 5, wherein
said screw is passed through a washer and said washer is sandwiched between a head of said screw and said double-metal-foil dielectric substrate.

8. The MMIC-mounted substrate according to claim 1, further comprising a heat dissipation plate contacting a top surface of said MMIC, said heat dissipation plate including a plate portion and a screw portion, said plate portion and said screw portion formed in one piece, and said screw portion passed through said double-metal-foil dielectric substrate and said metal chassis to be caught on the rear side of said metal chassis.

9. A transmitter device for transmission only in microwave-band communication, having an MMIC-mounted substrate as recited in claim 1.

10. A transceiver device for transmission/reception in microwave-band communication, having an MMIC-mounted substrate as recited in claim 1.
